(19) United States
(12) Patent Application Publication
(10) Pub. No.: US 2006/0137609 A1
(43) Pub. Date: Jun. 29, 2006

(54) Multi-single wafer processing apparatus

(76) Inventors: Jerzy P. Puchacz, Pleasanton, CA (US); Sasangan Ramanathan, San Ramon, CA (US); Manolito Q. Reyes, Poway, CA (US); Thomas E. Seidel, Sunnyvale, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/224,767

(22) Filed: Sep. 12, 2005

Related U.S. Application Data
(60) Provisional application No. 60/609,598, filed on Sep. 13, 2004.

(51) Int. Cl. C23C 16/00

(52) U.S. Cl. 118/719

(57) ABSTRACT

A wafer processing apparatus includes one or more processing modules, each having multiple, distinct, single-wafer processing reactors configured for semi-independent ALD and/or CVD film deposition therein; a robotic central wafer handler configured to provide wafers to and accept wafers from each of said wafer processing modules; and a single-wafer loading and unloading mechanism that includes a loading and unloading port and a mini-environment coupling the loading and unloading port to the robotic central wafer handler. The wafer processing reactors may be arranged (i) along axes of a Cartesian coordinate system, or (ii) in quadrants defined by said axes, one axis being parallel to a wafer input plane of the at least one of the process modules to which the single-wafer processing reactors belong. Each processing module can include up to four single-wafer processing reactors, each with an independent gas distribution module.

### RELATED APPLICATION

The present application is a non-provisional of, claims priority to and incorporates by reference U.S. Provisional Patent Application 60/609,598, filed Sep. 13, 2004.

### FIELD OF THE INVENTION

The present invention relates to a configuration for a semiconductor wafer processing (e.g., atomic layer deposition, chemical vapor deposition, plasma vapor deposition, cleaning or etching, etc.) apparatus having multiple, single-wafer processing chambers (reactors).

### BACKGROUND

In the field of thin film technology, larger production yields and higher productivity have been, and continue to be, driving forces behind the development of new wafer processing apparatus. For example, many atomic layer deposition (ALD) systems now being used commercially employ a batch processing approach wherein substrates to be coated are arranged in different planes, and wherein relatively large numbers of substrates are coated in a single reactor simultaneously. The popularity of such devices is due largely because ALD has an inherently lower deposition rate than competing processes. By processing several substrates at the same time (in parallel) in a batch reaction chamber, total wafer throughput can be increased.

Unfortunately, batch processing has some inherent disadvantages, and addressing the throughput limitations of ALD by batch processing seems to trade one set of problems for another. For example, in batch processor systems cross-contamination of substrates poses a significant problem. Batch processing also inhibits process control, process repeatability from substrate to substrate and batch to batch, and necessitates post-processing film-removal solutions for backside deposition. All of these factors severely affect overall system maintenance, yield, reliability, and therefore net throughput and productivity.

What is needed therefore is a high productivity ALD system architecture that allows multiple substrates to be processed while still providing attractive throughput and yield, and which at the same time conservatively uses expensive clean room and associated production floor space.

One prior solution that attempts to address this need is described in U.S. Pat. No. 5,855,681 of Maydan et al. In particular, the '681 patent describes a semiconductor wafer processing apparatus that includes multiple processing chambers, each with a pair of single wafer processing regions. The processing regions of each chamber are isolatable from each other but share a common gas supply and common exhaust pump. The processing chambers are configured to allow multiple, isolated processes to be performed concurrently in the different processing regions, so that a pair of wafers can be processed simultaneously in each chamber. Each processing region of each processing chamber is connected to a common transfer chamber, which includes a wafer handler adapted to transfer simultaneously two wafers from a load lock chamber to the twin processing regions of a processing chamber.

The '681 patent points out that the processing regions of each processing chamber are isolatable from one another inasmuch as the “processing regions have a confined plasma zone separate from the adjacent region which is selectively communicable with the adjacent region via an exhaust system.” However, the gas lines which provide gas into the gas distribution system within each processing region are connected to a single, common gas source line and are therefore shared or commonly controlled for the delivery of gas to each processing region of a chamber:

The '681 design appears to preclude more than 2 processing regions per processing module with respect to loading, and limits the assembly of more than 2×3 processing regions within a relatively small footprint. Thus, while the solution proposed in the '681 patent does provide for some of the benefits of single wafer processing in a batch-type environment, there are limits as to the number of wafers which can be processed at a time.

### SUMMARY OF THE INVENTION

In one embodiment of the present invention, a wafer processing apparatus includes one or more processing modules, each processing module having multiple, distinct, single-wafer processing reactors configured for semi-independent ALD and/or CVD film deposition therein; a robotic central wafer handler configured to provide wafers to and accept wafers from each of said wafer processing modules; and a single-wafer loading and unloading mechanism that includes a loading and unloading port and a mini-environment coupling the loading and unloading port to the robotic central wafer handler. The wafer processing reactors of any or all the processing modules may be arranged for wafer processing (i) along axes of a Cartesian coordinate system, or (ii) in quadrants defined by said axes, one axis of said coordinate system being parallel to a wafer input plane of the at least one of the process modules to which the single-wafer processing reactors belong. Each processing module can include up to four single-wafer processing reactors and preferred arrangements include 3 or 4 such reactors per module. Each of the single-wafer processing reactors of each processing module includes an independent gas distribution module.

The wafer processing apparatus may further include a chemical source sub module stacked atop a processing chamber containing the single-wafer processing reactors, and an electrical controller sub module stacked atop the chemical source sub module. The electrical controller sub. module and the chemical source sub module may be vertically displaceable from each other and from the processing chamber along one or more guide posts.

A further embodiment of the present invention includes a wafer processing module having up to four (and, preferably 3 or 4) semi-independent process zones arranged (i) in quadrants of, or (ii) along axes of a Cartesian coordinate system, one axis of said coordinate system being parallel to a wafer input plane of the process module, said process zones being configured for wafer processing such that reactant leakage from a subject one of the process zones to adjacent process zones thereof occurs in an amount no more than 5×10⁻² times the reactant deposition rate in the subject process zone. The process zones are preferably equally accessible by a wafer indexer configured to load/unload wafers to/from the semi-independent process zones. Each of the semi-independent process zones may include an independent gas distribution module and/or the semi-independent process zones may share a common gas exhaust system (e.g., arranged so as to provide azimuthally-symmetric exhaust from each of the semi-independent process zones).

A still further embodiment of the present invention provides a wafer process module having a stack of electrical controls and gas source modules with said gas source modules being coupled to a reactor lid, the stack being capable of vertical motion and guided separation from a reactor chamber thereunder, thereby providing for removal of the lid, the electrical controls and the gas source modules collectively, or individually.

Another embodiment of the present invention provides for wafer handling by moving single wafers into or out of multi-single wafer reaction chamber zones using individual wafer end effectors of an indexer to sequentially accept wafers from a central vacuum robotic wafer handler, and to place said wafers substantially simultaneously on reactor susceptors within each reaction chamber zone.

### BRIEF DESCRIPTION OF THE DRAWINGS

The present invention is illustrated by way of example, and not limitation, in the figures of the accompanying drawings, in which:

FIG. 1 illustrates a top plan view of wafer processing apparatus configured in accordance with an embodiment of the present invention with two process modules and one cooling station.

FIG. 2 illustrates a further top plan view of a wafer processing apparatus configured in accordance with another embodiment of the present invention with a single process module and one cooling station.

FIG. 3 illustrates a wafer processing apparatus configured in accordance with yet a further embodiment of the present invention having three processing modules.

FIG. 4 illustrates a wafer processing apparatus configured in accordance with an additional embodiment of the present invention and having three processing modules.

FIG. 5 illustrates top and side views of two different multi-single wafer array processing module layouts, each configured in accordance with various embodiments of the present invention.

FIG. 6 illustrates a process module configured in the quadrant design which is one embodiment of the present invention, and shown with all major sub modules in processing position.

FIG. 7 illustrates a process module configured in accordance with the quadrant design, which is an embodiment of the present invention, and shown with an electrical controller sub module in an elevated service position, providing access to a gas source module.

FIG. 8 illustrates a process module configured in accordance with the quadrant design of the present invention, and shown with electrical and gas source sub modules in an elevated service position, providing access to a process chamber.

FIG. 9 illustrates a reaction chamber lid having the quadrant configuration in accordance with an embodiment of the present invention.

FIG. 10 is a cut-away view of a reaction chamber housing having the quadrant configuration in accordance with an embodiment of the present invention.

FIG. 11 is a plan view of a reaction chamber housing having the quadrant configuration in accordance with an embodiment of the present invention.

FIG. 12 is a plan view of a reaction chamber housing having the quadrant configuration in accordance with an embodiment of the present invention.

FIG. 13 is a cut-away view of a wafer processing apparatus configured in accordance with an embodiment of the present invention showing wafers over susceptors, and the indexer rotated away from the wafers.

FIG. 14 shows an example of indexer sequencing and wafer hand-off sequencing for a wafer processing apparatus configured in accordance with an embodiment of the present invention.

### DETAILED DESCRIPTION

Described herein is a unique configuration for a semiconductor wafer processing (e.g., atomic layer deposition, chemical vapor deposition, plasma vapor deposition, cleaning or etching, etc.) apparatus having multiple, single-wafer processing chambers. In the present description there are a number of details set forth in order to provide readers with a thorough understanding of the present invention, however, it will be apparent to those of ordinary skill in the art that there are many alterations in detail and scale that may be made in the embodiments described herein without departing from the spirit and scope of the present invention. For example, there are many wafer sizes presently in use in integrated circuit manufacturing, and processing stations configured according to embodiments of the present invention may be constructed to accommodate individual wafer sizes or a range of wafer sizes. Furthermore, in addition to the features described in detail below, embodiments of the present invention may include some or all of the features of related wafer processing apparatus developed at least in part by some of the present inventors and described in the following patents and patent applications assigned to the assignee of the present invention, each of which is incorporated herein by reference:
a. U.S. Pat. No. 6,387,185 entitled “Processing chamber for atomic layer deposition processes”. This patent describes a processing station adaptable to standard cluster tools and which has a vertically translatable pedestal having an upper wafer-support surface including a heater plate adapted to be plugged into a unique feed-through in the pedestal. At a lower pedestal position, wafers may be transferred to and from the processing station, and at an upper position the pedestal forms an annular pumping passage with a lower circular opening in a processing chamber. A removable, replaceable ring at the lower opening of the processing chamber allows pumping speeds to be tailored for different processes by replacing the ring. In some embodiments the pedestal also has a surrounding shroud defining an annular pumping passage around the pedestal. A unique two-zone heater plate is adapted to the top of the pedestal, and connects to a unique feed-through allowing heater plates to be quickly and simply replaced. In some embodiments the top of the processing chamber is removable, allowing users to remove either pedestals or heater assemblies, or both, through the open top of a processing station.
b. U.S. Pat. No. 5,879,459 entitled “Vertically-stacked process reactor and cluster tool system for atomic layer deposition”. This patent describes a low profile, compact atomic layer deposition reactor (LP-CAR) that has a low-profile body with a substrate processing region adapted to serve a single substrate or a planar array of substrates, and a valved load and unload port for substrate loading and unloading to and from the LP-CAR. The body has an inlet adapted for injecting a gas or vapor at a first end, and an exhaust exit adapted for evacuating gas and vapor at a second end. The LP-CAR has an external height no greater than any horizontal dimension, and more preferably no more than two-thirds any horizontal dimension, facilitating unique system architecture. An internal processing region is distinguished by having a vertical extent no greater than one-fourth the horizontal extent, facilitating fast gas switching. In some embodiments one substrate at a time is processed, and in other embodiments there may be multiple substrates arranged in the processing region in a planar array. The compact reactor is distinguished by individual injectors, each of which comprises a charge tube formed between a charge valve and an injection valve. The charge valve connects the charge tube to a pressure regulated supply, and the injection valve opens the charge tube into the compact reactor. Rapidly cycling the valves injects fixed mass-charges of gas or vapor into the compact reactor. Multiple such compact reactors are stacked vertically, interfaced into a vacuum-handling region having a Z-axis robot and a load/unload opening.
c. U.S. Published Patent Application 2003/0109094 entitled “Massively parallel atomic layer deposition/chemical vapor deposition system”. This patent application describes a method and apparatus for the use of individual vertically stacked ALD or CVD reactors. Individual reactors are independently operable and maintainable. The gas inlet and output are vertically configured with respect to the reactor chamber for generally axi-symmetric process control. The chamber design is modular in which cover and base plates forming the reactor have improved flow design. A plurality of ALD/CVD reactors have a compact, low vertical profile so that the reactors may be vertically stacked. The stacked deposition reactors are coupled to receive a material, such as a semiconductor wafer, from a load lock unit to place in one of the reactors. In one embodiment, separate load lock units corresponding to the reactors are used, so that the wafer may be vertically positioned to the respective height of the vertically stacked reactors when the wafers are to be located in the load lock. The vertically stacked ALD/CVD reactors have a low height profile, but allow separate gas inlet at the top of a chamber and separate exhaust at the bottom of the chamber to provide a generally axi-symmetric vertical gas flow across the wafer when the wafer is processed in the reactor chambers. The vertical arrangement allows multiple wafers to be processed separately in module housing the multiple reactors. In one embodiment, the reactor chamber is formed by placing a top plate and a bottom plate onto a frame. The top plate and the bottom may each have a particularly shaped recessed region to form the top and bottom of the chamber conforming to the particular shape. In one embodiment, the top and bottom of the chamber has a cone-shape to improve the generally axi-symmetric gas flow in the chamber. In another embodiment, horn-shaped chamber is used to provide an option to further improve the gas flow. The low profile reactors are individually constructed with a cover plate integrated with and containing a horizontal input conduit and a base plate integrated with and containing a horizontal conduit for exhaust to minimize the total vertical height of the assembled low profile reactors.

As more fully described below with reference to the accompanying drawings, the present multi-single wafer architecture provides a throughput enhancement over conventional systems by a factor of 8 or 12 to 3 or 4 (i.e., 8/3 or 12/4, where the reference number of reactors per process module is 3 and 4, respectively), in the same or smaller footprint. Conventional systems typically have an “a real productivity metric” of about 3 wph/m² (e.g., 30 wph in 10 m²) and use a standard robotic central handler using 3 or 4 single wafer process chambers. In contrast, the present wafer processing apparatus uses up to three process modules (described further below), each of which have up to (and preferably) four multiple single wafer (MSW) reactors. The invention is also applicable for use with dozens to hundreds of smaller piece parts that may placed on carriers whose sizes are substantially the same as 200 or 300 mm diameter. The reactor design for the present wafer processing apparatus may be optimized by using an array of four, semi-independent reactors within a given process module. The reactors may be laid out in an “on-axis” configuration within the process module, or, preferably, in an “in-quadrant” configuration, which provides for certain floor space and process control advantages. As illustrated in the accompanying drawings, the wafer processing apparatus may utilize a stacked supporting module configuration in which such modules are vertically movable for access to and service of chemical sources, electrical controls, and reactor lids. Further, the present wafer processing apparatus includes a unique indexing mechanism that allows for efficient loading and unloading of the reactor chambers.

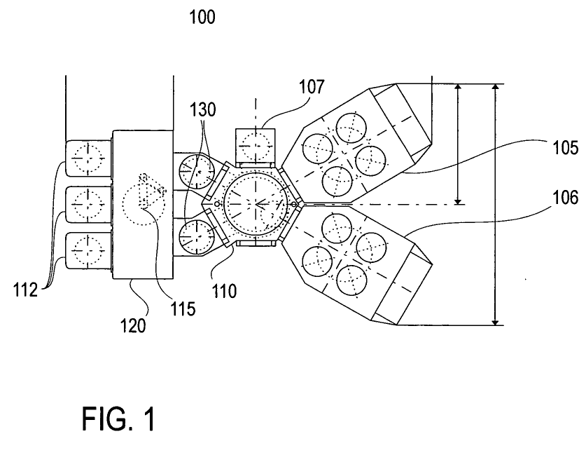

Referring first to FIG. 1, a wafer processing apparatus (100) is configured in accordance with an embodiment of the present invention with two process modules (105, 106) and one cooling station (107) and is illustrated in top plan view. This wafer processing apparatus includes a compact central robotic vacuum wafer transport handler (110), which may be configured similarly to that described in one or more of the above-cited patents/patent applications and preferably meets MESC-SEMI standards. Each of the two process modules includes four, semi-independent, single wafer reactors. In the illustration these reactors are shown in the “in quadrant” configuration (discussed further below). A wafer processing apparatus implementation such as is illustrated in the diagram is capable of processing approximately 6 wph/m². In the present context, “semi-independent” means that a given reactor may have reactants leaking from its own reaction zone onto the indexer arm mechanism or out adjacent reactors in an amount characterized by no more than 5×10⁻², and preferably 10⁻³ or less, of the deposition rates in its own reaction zone.

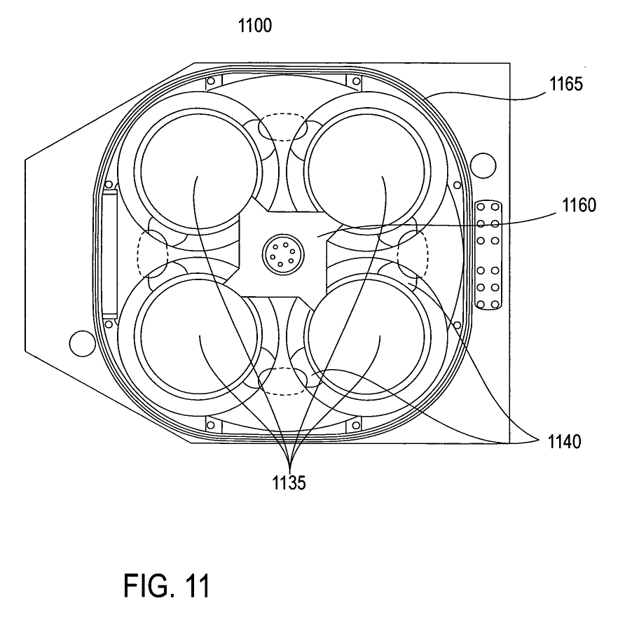

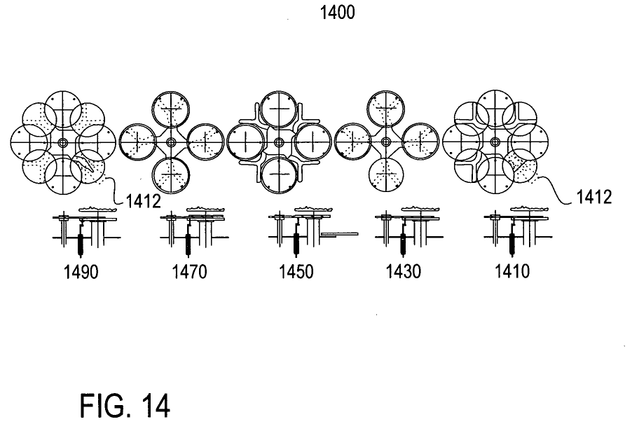

The wafer processing apparatus (100) is illustrated with three conventional FOUP loading modules (112), a conventional mini-environment with an atmospheric robotic wafer transfer (120) to two 25 wafer capacity vacuum load locks (130) utilizing 2 to 25 wafers. If desired, a wafer aligner may be placed in the mini-environment but such a configuration is not shown here. The wafer processing apparatus (100) may be implemented in a 300 mm or 200-300 mm bridge configuration. The modules have shared pumping but may have or may not have independent precursor feed injection above the substrate surface. Independent precursor feed provides for some flexibility and control in matching film deposition characteristics. Included within each process module (112) of the wafer processing apparatus (100) is a unique wafer pick and place indexer mechanism configured to move wafers to each single wafer reactor of a respective process module (112). The indexer design is shown in detail in FIGS. 11, 12 and 13, discussed further below. The functional operation of the indexer is described below with reference to FIG. 14.

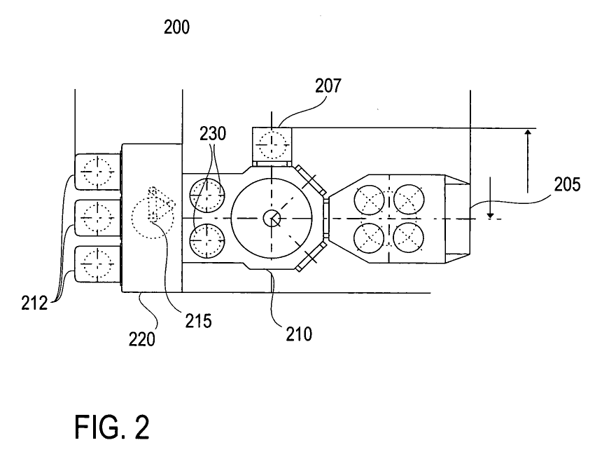

FIG. 2 illustrates a further embodiment of a wafer processing apparatus (200) (which may also be termed a transport module) with a single process module (205) and one cooling station (207) in top plan view. This embodiment of the present invention includes a conventional central robotic vacuum wafer transport handler (210) and a single process module having four, semi-independent, single wafer reactors in the in-quadrant configuration. Such an implementation is capable of processing approximately 4.4 wph/m².

The wafer processing apparatus (200) is illustrated with three conventional FOUP loading modules (212), a conventional mini-environment with an atmospheric robotic wafer transfer (220) to two vacuum load locks (230) of 2 to 25 wafer capacity. If desired, a wafer aligner may be placed in the mini-environment but such a configuration is not shown here. This configuration has a high system performance metric for smaller, limited production granularity and may be implemented in a 300 mm or 200-300 mm bridge configuration. The process module has shared pumping but independent precursor feed injection above the substrate surface.

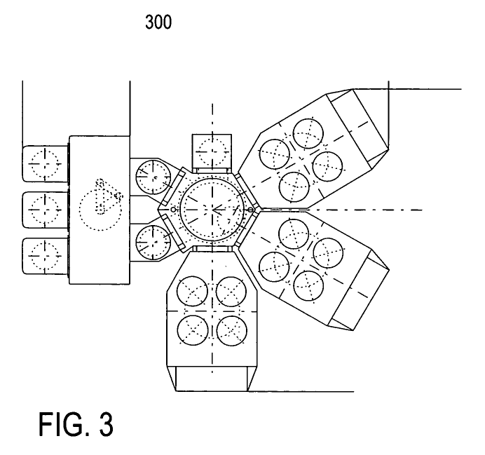

FIG. 3 illustrates a wafer processing apparatus (300) configured substantially similar to the wafer processing apparatus (100) shown in FIG. 1, but having three processing modules capable of processing (theoretically) approximately 7.5 wph/m², assuming no loading limitations. In practice, wafer loading limits may limit the a real productivity.

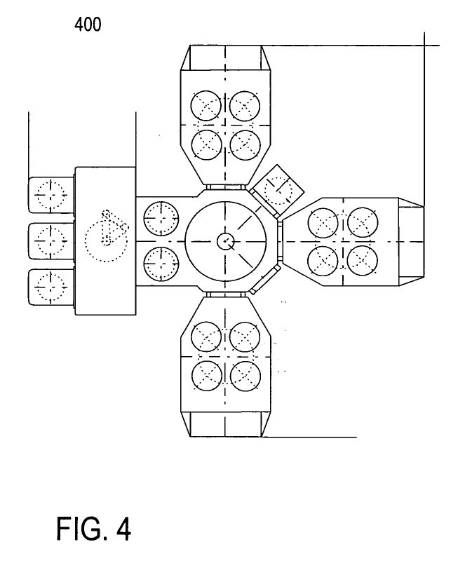

FIG. 4 illustrates a wafer processing apparatus (400) configured substantially similar to the wafer processing apparatus (200) shown in FIG. 2, but having three processing modules capable of processing approximately 10 wph/m², assuming no loading limitations. As with the other configurations described herein, wafer loading limits may limit the a real productivity. Although all illustrations have been shown with 4 single wafer reactors in each process module, advantageous configurations with 3 single wafer reactors per process module may also be assembled within the scope of the present invention. For the 3 reactor per process module configuration, the quadrant (with 90° compartments) configuration is replaced by a triad (with 120° compartments) configuration.

Similarly, process modules housing more than 4 single wafer reactors may be used and are considered to be within this scope of the present invention. For example, modules housing 5, 8, or other numbers of reactors may be used. In such cases, the indexer apparatus described herein would need to be modified to accommodate the appropriate number of wafers. In some cases, this may mean departing from the central, circular indexer design discussed below and, instead, adopting an indexer that includes linear translation motion as well as rotational (e.g., one which resembles a race track around or between the periphery of the reactors housed within the process module; or a central, linear track arrangement between the reactors, which may be arranged on alternate sides thereof).

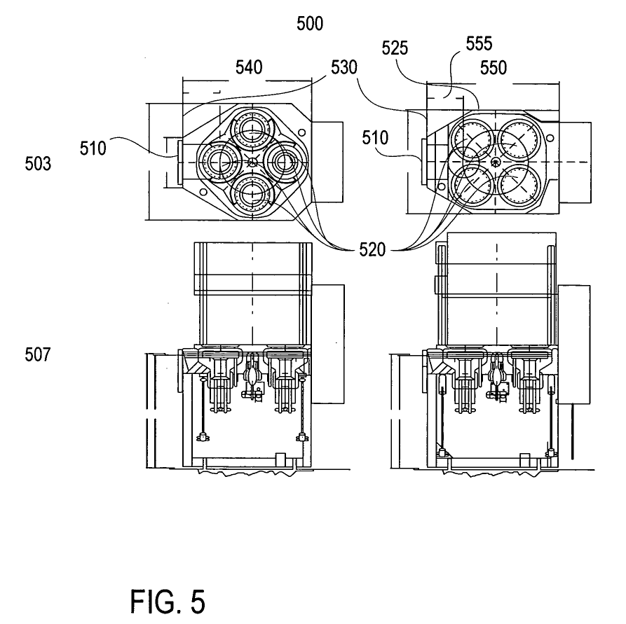

FIG. 5 illustrates top and side views of two different multi-single wafer array processing module layouts, each with four wafer capacity (500). The upper drawings in the illustration are top plan views (503) and the lower drawings are side views (507) of the respective devices. Both configurations have a wafer input port (510) on the left for load (west position) and use a four wafer array process modules. The four, semi-independent, chamber areas (520) form an array that can be inscribed within a square-like perimeter (525), the side of the square-like perimeter being at 45° (also 135°) to the plane of the input port (530) for the left layout (540) and at 0° (also 90°) to the plane of the input port (530) for the right layout (550). The layout on the left (540) is termed an “on-axis” or simply “axis” layout and the layout on the right (550) is called an “in-quadrant” or “quadrant” layout. These terms are used because wafers in the quadrant layout are located in the quadrants of a Cartesian coordinate system (i.e., each wafer lies in its own quadrant), while in the axis design the wafers lie on the axes of the Cartesian coordinate system. In each case, one axis of the Cartesian coordinate system is presumed to pass through the wafer loading slot (510) perpendicular to the “x” axis of the layout which is defined as the wafer “loading line.”

The quadrant layout configuration has a smaller module area (1911 sq. units vs. 2021 sq. units) than the axis layout, and also provides better packing density in the overall system architectures illustrated in FIGS. 1 and 3. Using the axis design is possible for these architectures, but will result in a larger footprint for the same throughput and functionality. The remaining features of the multiple single wafer apparatus will be discussed and illustrated using a quadrant layout, however in each instance an axis layout could be used.

To load the wafers in each reactor, an indexer (described further below), having wafers loaded thereon, is rotated about a central axis of the process module. An entry load circle position is illustrated by a circle centered some distance (555) from the plane of the input port (530) in the drawing illustrating the quadrant layout in the upper right portion of FIG. 5.

One of the benefits of the in-quadrant design is the sharing of perturbations caused by the effects of the wafer entrance slot valve. In the on-axis design, the perturbation is applied to a single wafer. Additionally, the effects of the slot valve may be offset by the use of a vertically movable susceptor as described in U.S. Pat. Nos. 5,855,675 and 6,174,377, both assigned to the assignee of the present invention and incorporated herein by reference.

Thus, in some embodiments, the present invention provides a process module having up to four independent process zones, said zones arranged for wafer processing in quadrants of a Cartesian coordinate system, the axes of said coordinate system being parallel and/or perpendicular to the wafer input plane of the process module. The in quadrant (or axis) reactor zones may be used in an apparatus for ALD and/or CVD film deposition or other single wafer processes such as plasma, cleaning or etching processes having an architecture consisting of one or more multiple, semi-independent, wafer process modules.

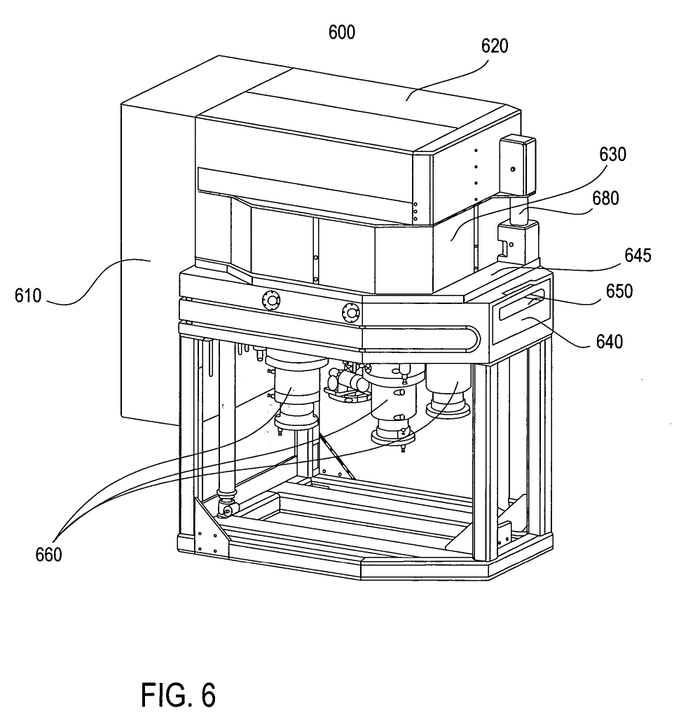

FIG. 6 illustrates a process module (600) configured in the quadrant design, and shown with all major sub modules in processing position. The back module is a gas box (610). The uppermost module is an electrical controller box (620). Stacked underneath the electrical controller box is a chemical source module (630) and, in turn, stacked thereunder is the process chamber (640) containing the individual reactors laid out in the quadrant design within. A wafer entrance slot (650) is included, and individual wafer reaction cylinders housings (660) that contain the susceptor-heater hardware are also shown.

The stacked electrical, source module boxes and reaction chamber lid (645) may be moved vertically to elevate them relative to the process chamber (640) using parallel guiding support post(s) (680). This design provides for modular access to different sub modules and different service functions.

Thus, a wafer process module configured in accordance with embodiments of the present invention includes a stack of electrical controls and gas source modules with said source modules being coupled to a reactor lid. The entire stack is capable of vertical motion and guided separation from the reactor chamber, thereby providing the removal of the lid, the electrical controls and the source modules collectively, or individually.

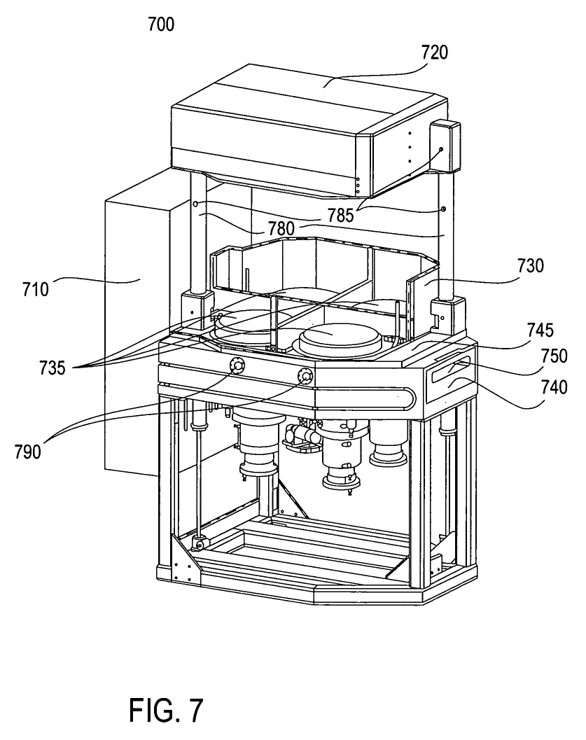

FIG. 7 illustrates a process module (700) configured in accordance with the quadrant design, and shown with the electrical controller sub module (720) in an elevated service position, providing access to the source module, with gas distribution modules (735) shown in the cut-away portion of the source module (730). The parallel guiding support posts (780) are indexed for height levels with latch set devices (785). Individual sub modules may be vertically elevated using powered lift mechanisms (not shown in detail).

Other features of the overall wafer processing apparatus are similar to those described above. The back module is a gas box (710). Stacked thereunder is a chemical source module (730), which is stacked on the process chamber (740) containing the reactors laid out in the quadrant design within. A wafer entrance slot (750) is included, and individual wafer reaction cylinders housings (760) that contain the susceptor-heater hardware are also shown. Ports (770) are provided for viewing, as required.

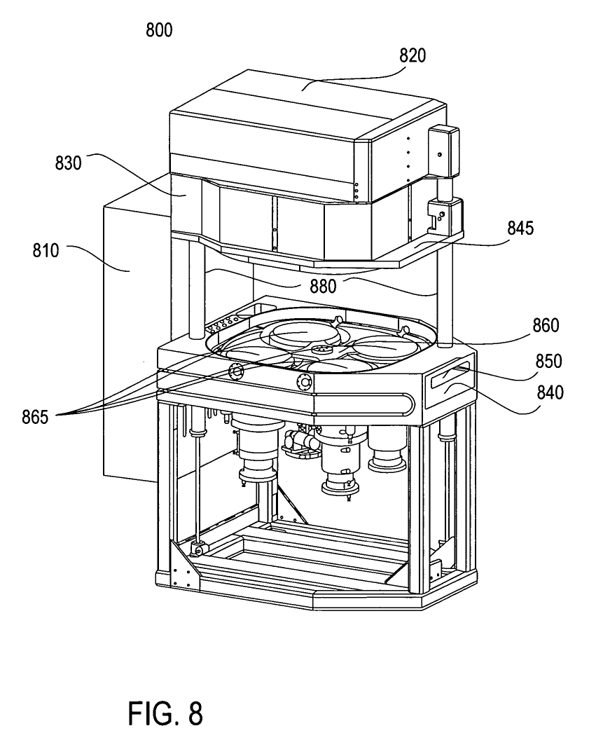

FIG. 8 illustrates a process module (800) configured in accordance with the quadrant design, and shown with the electrical and source module sub modules in an elevated service position, providing access to the process chamber. The stacked electrical box (820), source module box (830) and reaction chamber lid (845) are moved vertically to elevate them relative to the process chamber (840) using a guiding support post (880). The process chamber with wafers (865) held by indexer (860) are in the lifted position over the quadrant susceptors. Other features of this embodiment of the present invention are similar to those discussed above. The back module is a gas box (810) and a wafer entrance slot (850) is provided.

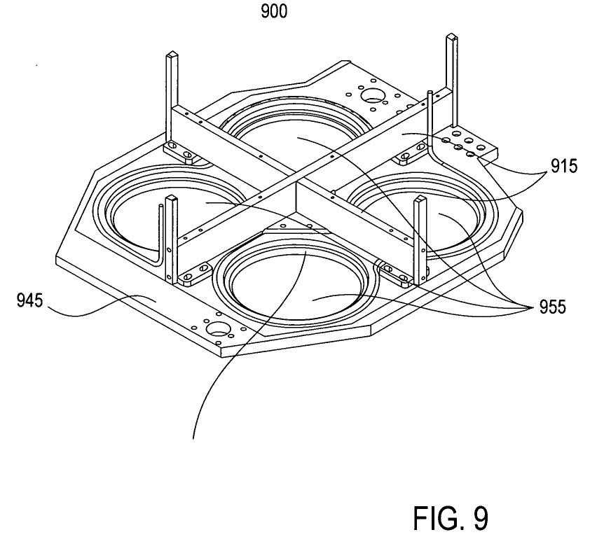

FIG. 9 illustrates a reaction chamber lid (900) having the quadrant configuration. The lid plate (945) is structurally reinforced with cross-beams (915), which are used to provide stiffness to the lid under evacuation of the reaction chamber. Temperature control trace lines (925) surround the receptor areas (955) for the gas distribution modules.

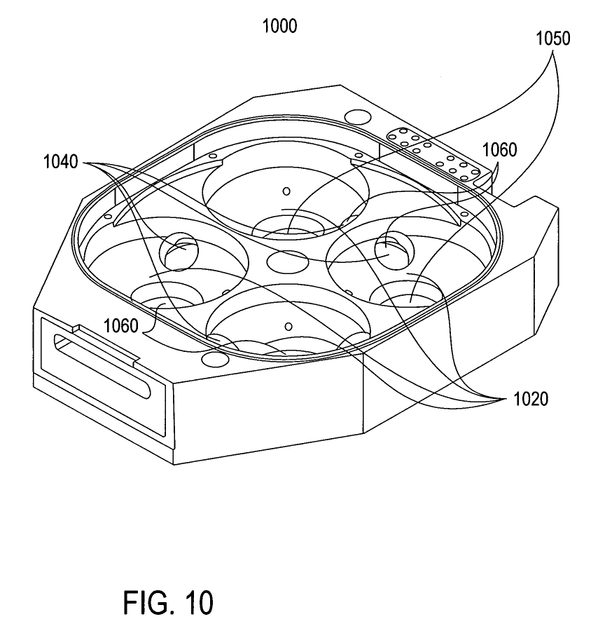

FIG. 10 is a cut-away view of a reaction chamber housing (1000) having the quadrant configuration. Four spatial cavity regions (1020) with diameters somewhat larger than the wafer diameter (e.g., 300 mm in one embodiment) are cut out for placement of the susceptor-heaters. In one embodiment, each individual sub-chamber cavity has two non-symmetric gas outlet conduits (1040) that connect to a downstream common pump. Each conduit, in turn, is connected to an adjacent quadrant conduit (1050) that runs below the housing. Computer modeling has been used to confirm that the gas flow profiles and velocities over the wafer surface are similar to a case where the outlet conduit is azimuthally symmetric. In other cases a more azimuthally symmetric conduit designs may be used. A symmetric flow and azimuthal pressure symmetry metric better than 10% and preferably better than 2% may be desirable. Other conduit designs than the one shown in FIG. 10 are considered to be within the scope of the present invention. In the center of each heater-reactor spatial regions are large cuts (1060) providing for the vertically movable susceptor-heater components as described below.

FIG. 11 is a plan view of a reaction chamber housing (1100) having the quadrant configuration. The wafer pick and place indexer mechanism (1160) is shown within the process module chamber housing (1165); the indexer enables the moving of wafers (1135) from the central vacuum robotic wafer handler to each single wafer reactor. The indexer (1160) is capable of discrete angular motion, namely (4) four sequential 90° rotations for picking up (or dropping off) single wafers from (to) the central handler. Forty-five degree rotation with respect to these angular positions is also used. This is described in more detail with below with respect to FIG. 14. In this view the indexer (1160) has already been loaded with one wafer each and is holding wafers (1135) over the susceptor-heater positions in the wafer “place” (if the wafer is unprocessed) or “pick” (if the wafer is processed) position.

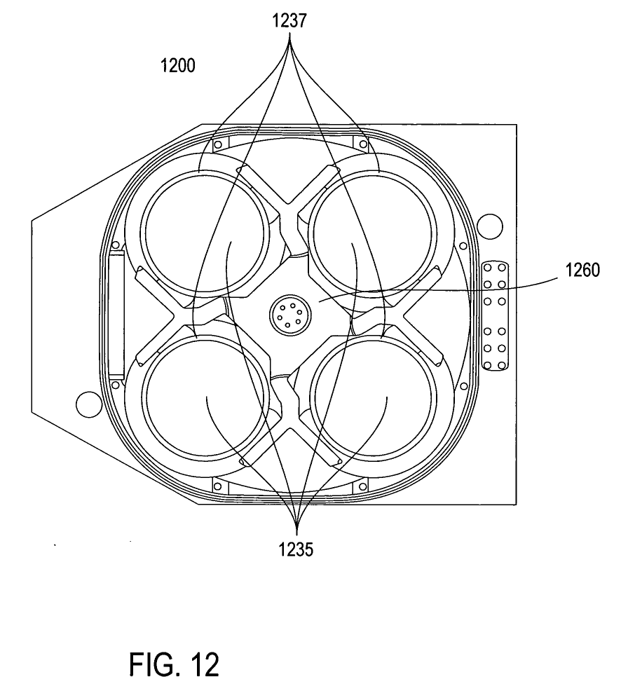

FIG. 12 is another plan view of a reaction chamber housing (1200) having the quadrant configuration. In this view the indexer (1260) is rotated 45° away from the wafer “place” or “pick” position. The wafers (1235) are on the susceptor-heaters in process positions. The susceptor-heater edges (1237) are visible.

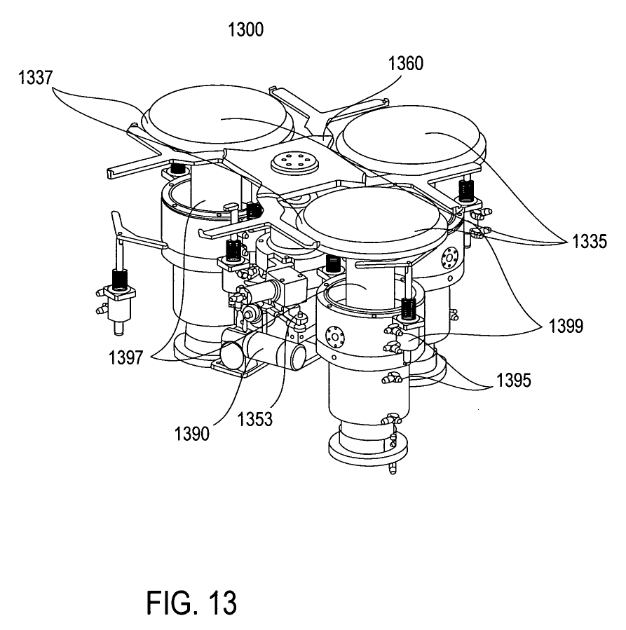

FIG. 13 is a cut-away view showing wafers (1335) over susceptors (1337), and the indexer (1360) rotated away from the susceptors/wafers. Also illustrated are indexer motor drive (1390) and 45° self-limiting linkage driver (1393), air cylinder drivers (1395) and a displaced vertically movable susceptor (VMS) (1397) is centered within the individual housings for the VMS. Three of the four susceptor-heaters are shown. The wafers (1335) are in the raised position above the susceptor surfaces (1337) and above the plane of the indexer (1360). The wafer lift pin drivers (1399) are shown, but different lifting devices may be used. The four-wafer indexer may be moved 45° or 90° and each such control is independent. The drive mechanism has built-in accelerate-de-accelerate capabilities.

FIG. 14 shows an example of the indexer sequencing and wafer hand-off sequencing (1400). Five views are shown: 1410, 1430, 1450, 1470, and 1490, which are described in sequence from right to left.

The first operation (shown in load view 1410) is wafer loading, whereby all four wafers are loaded onto the arms of the indexer in a chamber otherwise without wafers or precursor process gases. During this process, the four wafers are loaded sequentially on the indexer arms. An end effector (1412) is shown placing the last of 4 wafers on the indexer receiving arm at the south-east location. Once all four wafers have been loaded onto the indexer, the indexer is rotated by 45°, positioning the wafers over the centers of the susceptor-heaters (see view 1430). Two sets of circles are shown: one with wafers loaded onto the four arms of the indexer, and displaced 45° from the four quadrant wafer susceptor positions (for ease of drawing the indexer sequencing, these illustrations show the “axis layout” instead of the “quadrant layout,” but the operations described herein are equally applicable to both).

The second operation is placement. Placement view (1430) shows the four wafers being pin lifted above the plane of the indexer and in particular above the indexer's paddles or “grippers.” Once the wafers are above the plane of the indexer, the indexer is rotated by 45° so that its end effectors are positioned between the susceptor-heaters. The lift pins are retracted thus placing the wafers down on the susceptors with the indexer arms between the susceptors-heaters (see view 1450). A vertically translatable elevated susceptor-heater (pedestal) may be used to position the wafers in an optimal process zone with respect to gas distribution and annular pumping conduits as discussed in U.S. Pat. No. 6,387,185.

The third operation is process run. Process view (1450) shows the wafer processing apparatus configuration when precursors are to be exposed to the wafers surfaces. The indexer's end effectors remain out of the direct pathway of the precursors, allowing precursors to reactor with the wafer first. The indexer arms may be adapted to provide minimal impact on the gas flow during the deposition period. During depositions, the parasitic leakage depositions on the indexer are preferably less than 5×10⁻² of that in a given reactor.

The fourth operation is placement of wafers from the suceptor to the end effectors of the indexer, as illustrated in the next process view (1470). Once film deposition on the wafers is complete, a vertically translatable retracted susceptor-heater (pedestal) may be used to achieve a lower position, suitable for the wafer pick operation. Lift pins elevate the wafers above the plane of the indexer, and the indexer is rotated under the wafers. The lift pins retract and the wafers are placed on the end effectors of the indexer, over the centers of the susceptor-heaters as shown.

The fifth operation is unloading as illustrated in the unload view (1490). The indexer is rotated 45°, providing a wafer with a film deposited on it to face the exit (entrance) slot, viewed in the southeast direction of the unload view (1490). The wafers are then removed from the indexer one at a time via the end effector (1412) of the central wafer robotic wafer handler.

Of course, other loading/processing sequences than that described above may be used.

The system throughput is a function of the rate at which wafers can be loaded from a front opening unified pod (FOUP) (112, 212, 312, 412) into the batch load locks (130, 240, 340, 430) and from there through the central vacuum robotic chamber to the process module, as well as the process time. For a process module with 50 wph throughput, the system throughput will be approximately 46 wph. For a two process module system with an intrinsic gross throughput of 100 wph, the system throughput is approximately 75 wph, but this may be improved by enhancements in wafer handling. Thus, embodiments of the present invention provide a wafer handling apparatus and process for moving wafers into or out of multi-single wafer reaction chamber zones for the purpose of ALD or CVD film deposition. As indicated above, an embodiment of such an apparatus includes four receiving wafer end effectors, said end effectors being used to sequentially accept wafers from a central vacuum robotic wafer handler, and configured to place said wafers (substantially simultaneously) on the reactor susceptors for film deposition.

The present system may be operated in a parallel mode, wherein all wafer are processed together and simultaneously after wafers are loaded onto the susceptors. Alternately, a process may be run in one semi-independent station that is followed by another process. In the case of ALD, an exposure may be taking place in one process module, while a different exposure or a purge may be taking place on another process module. The present wafer processing apparatus may also be compatible with plasma enhanced processes, where remote or direct plasma hardware is configured with each semi-independent reactor. Sources for each quadrant may be parallel or independently fed. Pump configurations may be shared or independent.

The present system may be operated in a parallel mode, wherein all wafer are processed together and simultaneously after wafers are loaded onto the susceptors. Alternately, a process may be run in one semi-independent station that is followed by another process. In the case of ALD, an exposure may be taking place in one process module, while a different exposure or a purge may be taking place on another process module. The present wafer processing apparatus may also be compatible with plasma enhanced processes, where remote or direct plasma hardware is configured with each semi-independent reactor. Sources for each quadrant may be parallel or independently fed. Pump configurations may be shared or independent. Alternatively, or in addition, serial and/or parallel processing can be carried out in the reactors in one or more of the process modules. For example, in the case where the deposition rates are balanced, 2 reactors can run one process (e.g., a film type) and 2 reactors a different process (e.g., a different film type). In still another case, where the deposition rates are not balanced, a larger number of reactors can be dedicated to the lower deposition rate process and a smaller number of reactors used for the higher deposition rate process.

What is claimed is:

1. A wafer processing apparatus, comprising:
one or more processing modules, each processing module having (i) multiple, distinct, single-wafer processing reactors configured for semi-independent ALD and/or CVD film deposition therein, and (ii) a wafer pick and place indexer mechanism configured to provide wafers to/retrieve wafers from each single wafer processing reactor of each respective processing module; and
a robotic central wafer handler configured to provide wafers to and accept wafers from each of said processing modules.

2. The wafer processing apparatus of claim 1, wherein the single-wafer processing reactors of at least one of the processing modules are arranged for wafer processing along axes of a Cartesian coordinate system, one axis of said coordinate system being parallel to a wafer input plane of the at least one of the process modules to which the single-wafer processing reactors belong.

3. The wafer processing system of claim 1, wherein the single-wafer processing reactors of at least one of the processing modules are arranged for wafer processing in quadrants defined by axes of a Cartesian coordinate system, one axis of said coordinate system being parallel to a wafer input plane of the at least one of the process modules to which the single-wafer processing reactors belong.

4. The wafer processing system of either claim 2 or claim 3, wherein the at least one of the processing modules includes four single-wafer processing reactors.

5. The wafer processing apparatus of either claim 2 or claim 3, wherein each of the single-wafer processing reactors of the at least one of the processing modules includes an independent gas distribution module.

6. The wafer processing apparatus of either claim 2 or claim 3, wherein each of the single-wafer processing reactors of the at least one of the processing modules share a common gas exhaust system.

7. The wafer processing apparatus of either claim 2 or claim 3, further comprising a chemical source sub module stacked atop a processing chamber containing the single-wafer processing reactors, and an electrical controller sub module stacked atop the chemical source sub module.

8. The wafer processing apparatus of claim 6, wherein the electrical controller sub module and the chemical source sub module are vertically displaceable from each other and from the processing chamber along one or more guide posts.

9. A wafer process module, comprising up to four semi-independent process zones arranged in quadrants of a Cartesian coordinate system, one axis of said coordinate system being parallel to a wafer input plane of the process module, said process zones being configured for wafer processing such that reactant leakage deposition rate from a subject one of the process zones to adjacent process zones thereof is less than 5×10⁻² times a reactant deposition rate in the subject process zone.

10. The wafer process module of claim 9, wherein the process zones are equally accessible by a wafer indexer configured to load/unload wafers to/from the semi-independent process zones.

11. The wafer process module of claim 9, wherein each of the semi-independent process zones includes an independent gas distribution module.

12. The wafer process module of claim 9, wherein the semi-independent process zones share a common gas exhaust system.

13. The wafer process module of claim 12, wherein the common gas exhaust system is arranged so as to provide azimuthally-symmetric exhaust from each of the semi-independent process zones.

14. A wafer process module, comprising up to four semi-independent process zones arranged along axes of a Cartesian coordinate system, one axis of said coordinate system being parallel to a wafer input plane of the process module, said process zones being configured for wafer processing such that reactant leakage deposition rate from a subject one of the process zones to adjacent process zones is less than 5×10⁻² times a reactant deposition rate in the subject process zone.

15. The wafer process module of claim 14, wherein the process zones are equally accessible by a wafer indexer configured to load/unload wafers to/from the semi-independent process zones.

16. The wafer process module of claim 14, wherein each of the semi-independent process zones includes an independent gas distribution module.

17. The wafer process module of claim 14, wherein the semi-independent process zones share a common gas exhaust system.

18. The wafer process module of claim 17, wherein the common gas exhaust system is arranged so as to provide azimuthally-symmetric exhaust from each of the semi-independent process zones.

19. A wafer process module, comprising a stack of electrical controls and gas source modules with said gas source modules being coupled to a reactor lid, the stack being capable of vertical motion and guided separation from a reactor chamber thereunder, thereby providing for removal of the lid, the electrical controls and the gas source modules collectively, or individually.

20. A method for wafer handling, comprising moving single wafers into/out of multi-single wafer reaction chamber zones using individual wafer end effectors of a multi-wafer indexer mechanism of a process module housing each of said multi-single wafer reaction chamber zones to
(i) sequentially accept wafers from/provide wafers to a central vacuum robotic wafer handler, and
(ii) to place on/pick up said wafers substantially simultaneously on/from reactor susceptors within each reaction chamber zone.

21. A wafer processing apparatus, comprising:
one or more processing modules, each processing module having (i) multiple, distinct, single-wafer processing reactors configured for semi-independent ALD and/or CVD film deposition therein, and (ii) a wafer pick and place indexer mechanism configured to provide wafers to/retrieve wafers from each single wafer processing reactor of each respective processing module;
a robotic central wafer handler configured to provide wafers to and accept wafers from each of said processing modules; and
one or more vertically stacked sets of electrical and chemical sub-modules, each such set corresponding to one of the processing modules, the electrical and chemical sub-modules of each set being vertically displaceable from each other and from a process chamber of a respective one of the process modules along guide posts, each such process chamber housing the multiple, distinct, single-wafer processing reactors of the respective one of the processing modules.
